(19) United States
(12) Patent Application Publication
(10) Pub. No.: US 2024/0356496 A1
(43) Pub. Date: Oct. 24, 2024

(54) METHODS AND APPARATUS TO SHAPE TERMS IN DIGITAL PRE-DISTORTION

(71) Applicant: Texas Instruments Incorporated, Dallas, TX (US)

(72) Inventors: Pankaj Gupta, Bangalore (IN); Jawaharlal Tangudu, Bangalore (IN); Manchi Sankalkar Ajay, Bangalore (IN); Mathews John, Bangalore (IN); Jaiganesh Balakrishnan, Bangalore (IN); Neeraj Kumar Sharma, Bangalore (IN)

(21) Appl. No.: 18/615,831

(22) Filed: Mar. 25, 2024

(30) Foreign Application Priority Data
Apr. 20, 2023 (IN) 202341028639

(51) Int. Cl. H03F 1/32

(52) U.S. Cl. CPC H03F 1/3247

(57) ABSTRACT

An example apparatus includes: memory having a terminal, the memory to store machine-readable instructions and adjacent channel leakage data; and programmable circuitry having a terminal coupled to the terminal of the memory, the programmable circuitry to execute the machine-readable instructions to: determine a range of out-of-band frequencies responsive to adjacent channel leakage ratio data; generate weight values responsive to electromagnetic emissions within the range of out-of-band frequencies of a first signal; modify a pre-distortion function responsive to the weight values; and apply the modified pre-distortion function to generate a second signal, the second signal to exhibit fewer emissions in the range of out-of-band frequencies than the first signal during transmission.

### CROSS-REFERENCE TO RELATED APPLICATION

This patent application claims the benefit of and priority to Indian Provisional Patent Application Serial No. 202341028639 filed Apr. 20, 2023, which application is hereby incorporated herein by reference in its entirety.

### TECHNICAL FIELD

This description relates generally to digital pre-distortion (DPD) and, more particularly, to methods and apparatus to shape terms in DPD.

### BACKGROUND

Wireless communications technology enables a wide variety of electronic devices (e.g., mobile phones, tablets, laptops, etc.) to support the execution of increasingly diverse and complex workloads. The secure, efficient, and accurate exchange of information over a wireless medium includes technical challenges. One such technical challenge is attenuation, which refers to the continued dissipation of a signal as it traverses a medium. In general, a signal has more attenuation when crossing a wireless medium than when crossing a wired medium.

### SUMMARY

For methods and apparatus to shape terms in digital pre-distortion, a first example apparatus includes: memory having a terminal, the memory to store machine-readable instructions and adjacent channel leakage data; and programmable circuitry having a terminal coupled to the terminal of the memory, the programmable circuitry to execute the machine-readable instructions to: determine a range of out-of-band frequencies responsive to adjacent channel leakage ratio data; generate weight values responsive to electromagnetic emissions within the range of out-of-band frequencies of a first signal; modify a pre-distortion function responsive to the weight values; and apply the modified pre-distortion function to generate a second signal, the second signal to exhibit fewer emissions in the range of out-of-band frequencies than the first signal during transmission.

A second example apparatus includes processor circuitry having a terminal, the processor circuitry to generate adjacent channel leakage ratio data that describes a range of out-of-band frequencies; monitor circuitry having a first terminal coupled to the terminal of the monitor circuitry and a second terminal, the monitor circuitry to generate weight values responsive to electromagnetic emissions within the range of out-of-band frequencies of a first signal; parameter generator circuitry having a first terminal coupled to the second terminal of the monitor circuitry and a second terminal, the parameter generator circuitry to convert the weight values into shaping parameters; function applier circuitry having a first terminal coupled to the second terminal of the parameter generator circuitry and a second terminal, the function applier circuitry to use the shaping parameters to modify a pre-distortion function; and digital pre-distortion (DPD) corrector circuitry having a terminal coupled to the second terminal of the function applier circuitry, the DPD corrector circuitry to apply the modified pre-distortion function to generate a second signal; and power amplifier circuitry to amplify an amount of power used to transmit the second signal, wherein the second signal exhibits fewer emissions in the range of out-of-band frequencies than the first signal during transmission.

A third example apparatus includes monitor circuitry having a terminal, the monitor circuitry to: determine a range of out-of-band frequencies responsive to adjacent channel leakage ratio data; and generate weight values responsive to electromagnetic emissions within the range of out-of-band frequencies of a first signal; function applier circuitry having a first terminal coupled to the terminal of the monitor circuitry and a second terminal, the function applier circuitry to use the weight values to modify a pre-distortion function; and digital pre-distortion (DPD) corrector circuitry having a terminal coupled to the second terminal of the function applier circuitry, the DPD corrector circuitry to apply the modified pre-distortion function to generate a second signal, wherein the second signal exhibits fewer emissions in the range of out-of-band frequencies than the first signal during transmission.

### BRIEF DESCRIPTION OF THE DRAWINGS

FIG. 1 is a block diagram of an example environment including two communication devices.

FIG. 2 is a block diagram of an example implementation of the transmitter circuitry of FIG. 1.

FIG. 3 is a block diagram of an example implementation of the DPD circuitry of FIG. 2.

FIG. 4 is a block diagram of an example implementation of the DPD estimator circuitry of FIG. 3.

FIG. 5A is a block diagram of an example implementation of the shaping function circuitry of FIG. 4.

FIG. 5B is an example of operations performed by the shaping function circuitry of FIG. 4.

FIG. 6 are graphs illustrating example operations performed by the shaping function circuitry of FIG. 4.

FIG. 7 are additional graphs illustrating example operations performed by the shaping function circuitry of FIG. 4.

FIG. 8 is a flowchart representative of example machine-readable instructions or example operations that may be executed, instantiated or performed using digital logic hardware or a programmable circuitry implementation of the shaping function circuitry and shaping control circuitry of FIG. 4.

FIG. 9 is a flowchart representative of example machine-readable instructions or example operations that may be executed, instantiated, or performed using digital logic hardware or programmable circuitry to generate shaping parameters as described in connection with FIG. 8.

FIG. 10 is a block diagram of an example processing platform including programmable circuitry structured to execute, instantiate, or perform the example machine-readable instructions or perform the example operations of FIGS. 8 and 9 to implement the DPD estimator circuitry 316 of FIG. 3.

The same reference numbers or other reference designators are used in the drawings to designate the same or similar (functionally or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and boundaries may be idealized. In reality, the boundaries and lines may be unobservable, blended, or irregular.

To counteract signal attenuation, manufacturers may include power amplifier (PA) circuitry to boost the power of a signal before transmission over a medium. In some examples, the PA circuitry operates at an improved efficiency (e.g., a higher ratio of output power to input power) when operating in a high nonlinearity region instead of a high linearity region. In examples used herein, linearity refers to a measure of how well an input signal and a corresponding output signal can be linearly related (e.g., characterized using a linear equation). For an example, a device that amplified a signal with an ideal fixed gain that is the same across all frequencies would operate in a high linearity region.

While electronic devices can save power and resources by operating the PA circuitry at an improved efficiency in a non-linear region, the output signal can lead to increased adjacent channel leakage ratio (ACLR) and error vector magnitude (EVM). ACLR measures relative power at specified frequency offsets from an assigned channel of a transmitted signal with respect to the power transmitted within the assigned channel. EVM measures deviation of amplitudes and phase shifts of symbols in a transmitted signal from ideal constellation points. Accordingly, ACLR measures signal leakage outside an assigned frequency band, and EVM measures in-band signal quality loss. Therefore, an increase in ACLR or EVM results in a lower probability of a receiver properly decoding a received signal.

In some examples, manufacturers can operate PA circuitry at an improved efficiency by using DPD techniques to reduce the nonlinearity of the output of the PA circuitry. In general, the nonlinear output caused by PA circuitry can be characterized as a function ƒ(x), where x is the original input signal and ƒ is a distorting function. DPD techniques counteract nonlinearity by applying an inverse function, ƒ⁻¹(x), to the original input signal and providing the output to the PA circuitry. In some examples, the application of the inverse function ƒ⁻¹ is referred to as a pre-distortion. As a result of the pre-distortion, the PA circuitry outputs an amplified version of ƒ(ƒ⁻¹(x))=x, which is the original input signal.

Manufacturers may use a wide variety of DPD equations to define a pre-distortion function ƒ⁻¹. Two such examples are dynamic deviation reduction (DDR) equations and generalized memory polynomial (GMP) equations. In general, DDR equations leverage the fact that as an order of a term (e.g., x, x², x³, etc.) in the non-linear characterization of a PA circuit increases, the term has a smaller impact on the overall distortion caused by the PA circuit. As a result, a DDR equation can generate an accurate pre-distortion without the use of high-order terms.

Some solutions to implement DPD equations are generally inflexible in the sense that a given device only supports fixed terms in the equation (e.g., the non-linear characterization). Furthermore, some solutions may also restrict the DPD equation to a specific set of terms computed in hardware or software, which eliminates the option for an end user to adjust the pre-distortion in a manner that best suits their particular use case.

In general, the effectiveness of DPD techniques is limited by the bandwidth and power of the input signal. For example, telecommunication organizations have set industry standards that define a maximum amount of ACLR that a transmitted signal is allowed to exhibit. Transmitter devices generally struggle to meet such ACLR standards in situations in which the input signal has high power and high bandwidth (e.g., the signal is expected to be transmitted across a range of frequencies over 200 Megahertz (MHz) wide).

U.S. patent application Ser. No. 18/129,589 describes DPD estimator circuitry that determines a DPD equation in an adjustable manner. The DPD estimator circuitry within U.S. patent application Ser. No. 18/129,589 uses various learning architectures to determine coefficients of an equation including individually adjustable terms. U.S. patent application Ser. No. 18/129,589 is hereby incorporated by reference in its entirety.

In U.S. patent application Ser. No. 18/129,589, the accuracy of the pre-distortion applied to input signals is even across frequency (e.g., there is no frequency band whose pre-distortion is more or less accurate than another frequency band). Accordingly, while the DPD estimator circuitry within U.S. patent application Ser. No. 18/129,589 provides greater flexibility and reduced computational resource usage compared to other DPD techniques, the effectiveness of the DPD estimator circuitry in U.S. patent application Ser. No. 18/129,589 may be limited in high power and high bandwidth situations as described above.

Example methods, apparatus, and systems described herein apply a shaping function that alters the values of DPD coefficients such that pre-distortion of an input signal can vary across both time and frequency. In this way, the accuracy of pre-distortion can change across different portions of the frequency bands encapsulating and surrounding the transmitted signal. DPD estimator circuitry described in the teachings herein includes example shaping function circuitry that assigns weight values to frequency bands responsive to electromagnetic emissions indicated by analyzing signal profile data, out-of-band frequencies from ACLR profile data, and a feedback signal. The shaping function circuitry also converts the frequency-domain weights into time-domain shaping parameters. The shaping function circuitry then applies the shaping parameters (e.g., modifies the pre-distortion function) by modifying individual DPD coefficients such that pre-distortion occurs more accurately in some frequency bands than in others. As a result, the example shaping function circuitry enables DPD corrector circuitry to continue inverting nonlinear outputs (and therefore satisfy a greater number of ACLR standards) when an input signal exhibits high signal bandwidth and high power. The example DPD estimator circuitry also includes example shaping control circuitry that provides the option to disable the shaping function when DPD convergence has not yet reached a steady state, the signal profile data changes, or the ACLR profile data changes. Accordingly, some examples of the teachings herein reduce computational resource usage by only applying the shaping function when it is necessary to achieve additional performance improvements.

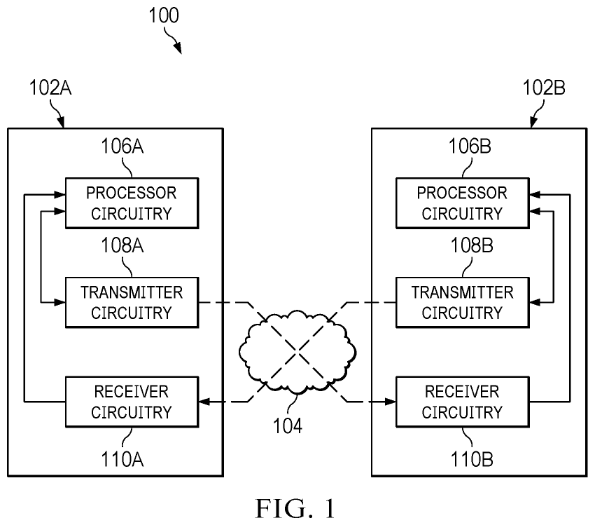

FIG. 1 is an example block diagram of a communication system. The example communication system 100 includes example devices 102A, 102B and an example wireless medium 104. The example device 102A includes example processor circuitry 106A, example transmitter circuitry 108A, and example receiver circuitry 110A. Similarly, the example device 102B includes example processor circuitry 106B, example transmitter circuitry 108B, and example receiver circuitry 110B.

The devices 102A and 102B communicate with one another across a wireless medium 104. The devices 102A and 102B may exchange any type of data, and use any type of control signals, when communicating. For example, the device 102A may send a handshake message to the device 102B prior to sending the data. After receiving the handshake message, the device 102B may send an acknowledgement message to the device 102A. The devices 102A and 102B may use any suitable protocol to communicate wirelessly, including but not limited to Wireless Fidelity (Wi-Fi)®, Bluetooth®, Near Field Communication (NFC), Orthogonal Frequency-Division Multiplexing (OFDM), Code-Division Multiple Access (CDMA), etc. In some examples, the communication system 100 includes a wired medium (e.g., a cable) in addition to or instead of the wireless medium 104. The device 102A may connect to any number of devices in addition to or instead of device 102V. For example, the device 102A may be implemented as a base station that communicates with both cell towers and mobile phones as part of a telecommunication network.

The processor circuitry 106A receives data from a source (e.g., an internal memory, the device 102B, etc.) and performs operations responsive to the data. For example, the example processor circuitry 106A generates a digital input signal to be provided to the example device 102B. Similarly, the processor circuitry 106B receives data from a source and performs operations responsive to the data. The processor circuitry 106A and the processor circuitry 106B may be any type of programmable circuitry. Examples of programmable circuitry include programmable microprocessors, Field Programmable Gate Arrays (FPGAs) that may instantiate instructions, Central Processor Units (CPUs), Graphics Processor Units (GPUs), Digital Signal Processors (DSPs), or microcontrollers and integrated circuits such as Application Specific Integrated Circuits (ASICs).

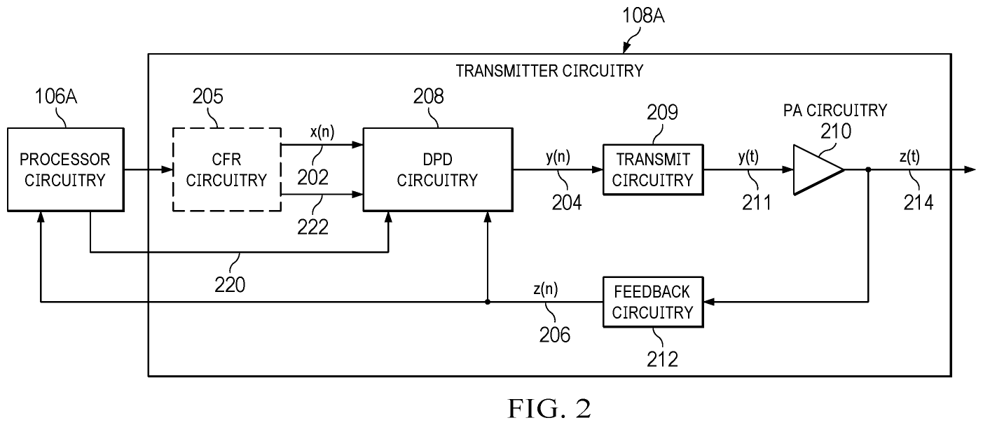

The transmitter circuitry 108A and the transmitter circuitry 108B receive digital signals from the example processor circuitry 106A and the example processor circuitry 106B, respectively. The transmitter circuitry 108A and 108B both pre-distort digital signals according to the teachings described herein, convert the digital signals into analog signals, amplify the power in the analog signal, and send the amplified signal over the wireless medium 104. The transmitter circuitry 108A is described further in connection with FIG. 2.

The receiver circuitry 110A receives the analog signal transmitted by the transmitter circuitry 108B. The receiver circuitry 110A converts the analog signal into a digital signal and provides the digital signal to the processor circuitry 106A. Similarly, the example receiver circuitry 110B receives the analog signal transmitted by the transmitter circuitry 108A. The receiver circuitry 110B converts the analog signal into a digital signal and provides the digital signal to the processor circuitry 106B.

In the example of FIG. 1, the transmitter circuitry 108A and 108B are implemented with DPD estimator circuitry that can use a shaping function to generate a function that pre-distorts an input signal unevenly across frequency. As a result, one or both the devices 102A and 102B can generate a signal exhibiting high bandwidth and high power in a manner that meets ACLR standards better and may produce fewer electromagnetic emissions (e.g., less noise) than other DPD techniques.

FIG. 2 is an example block diagram of the transmitter circuitry 108A of FIG. 1. FIG. 2 includes the processor circuitry 106A and the transmitter circuitry 108A. The transmitter circuitry 108A includes example Crest Factor Reduction (CFR) circuitry 205, example DPD circuitry 208, example transmit circuitry 209, example PA circuitry 210, and example feedback circuitry 212. Signals used by, generated in, or generated by the transmitter circuitry 108A include an example x(n) signal 202, an example y(n) signal 204, an example y(t) signal 211, an example z(n) signal 206, an example z(t) signal 214, example ACLR profile data 220, and example signal profile data 222.

The x(n) signal 202 represents a digital input signal. For example, the x(n) signal 202 in the foregoing example of FIG. 1 is a handshake message. The y(n) signal 204 is a pre-distorted version of the input signal, x(n). The z(n) signal 206 is a digital version of the analog z(t) signal 214. The z(t) signal 214 is an analog output signal generated by the PA circuitry 210. As described further below, the analog z(t) signal 214 is provided to an antenna of the transmitter circuitry 108A for transmission across the wireless medium 104, and the digital z(n) signal 206 is used to adjust the digital y(n) signal 204.

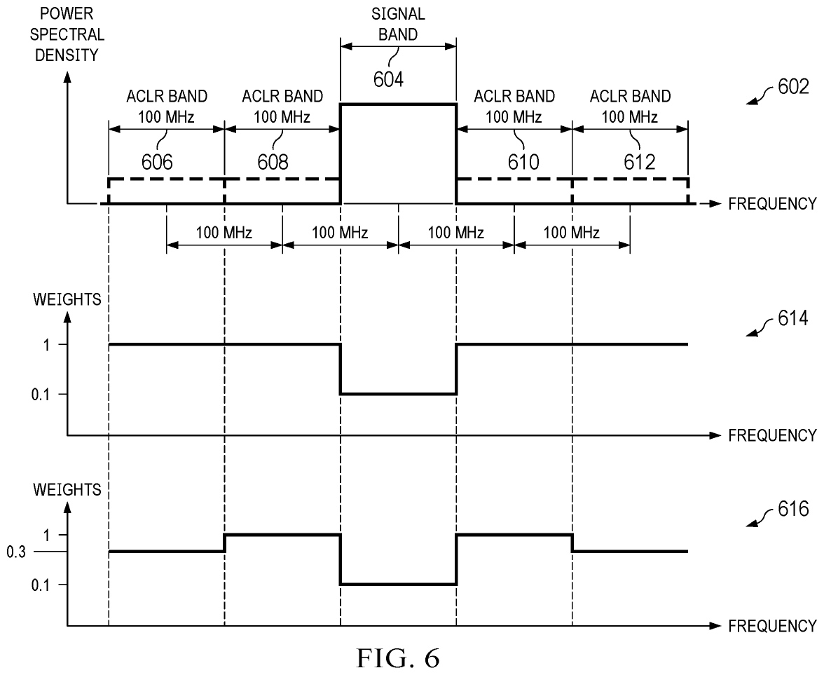

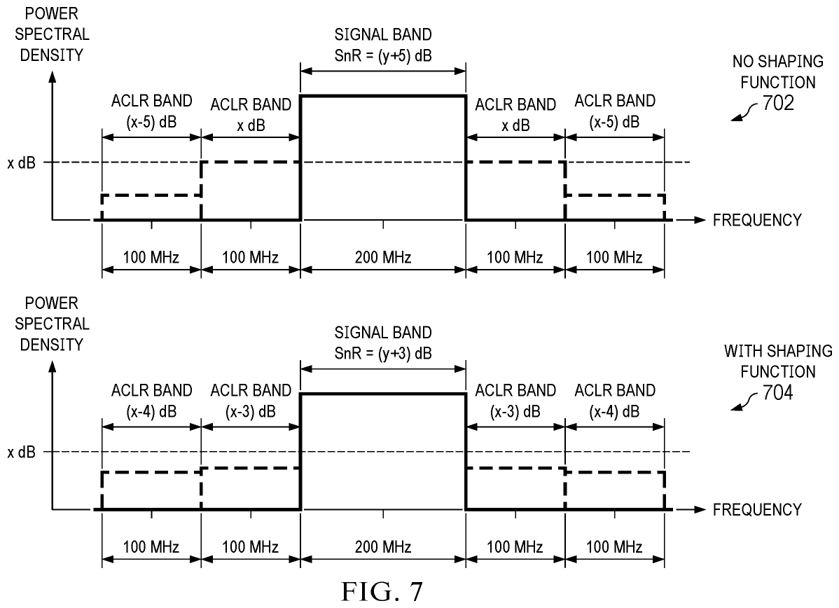

The ACLR profile data 220 defines one or more ranges of frequencies where ACLR is likely to be high (e.g., where electromagnetic noise is predicted to occur). In some examples, the ranges of frequencies defined in the ACLR profile data 220 are referred to as out-of-band frequency ranges or ACLR bands. The signal profile data 222 defines a range of frequencies that the transmitter circuitry 108A expects to keep the transmitted signal within. In some examples, the range of frequencies within the signal profile data 222 may be referred to as an in-band frequency range or a signal band. In the examples of FIGS. 6 and 7 described below, the signal band is a single, continuous range of frequency, and the ACLR bands form continuous regions of frequency adjacent to the signal band. In other examples, one or more of the signal band(s) and the ACLR bands may include multiple discontinuous ranges of frequencies. In general, the location and the size of the ACLR bands are responsive to the location and size of the signal band.

The CFR circuitry 205 reduces and removes peaks within a first digital signal produced by the processor circuitry 106A. In the example of FIG. 2, the output of the CFR circuitry 205 is the x(n) signal 202, a second digital signal that is used as input by the DPD circuitry 208. By reducing and removing peaks in the first digital signal, the CFR circuitry 205 reduces the Peak-to-Average power Ratio (PAR) and decreases the power consumption of the transmitter circuitry 108A.

In the example of FIG. 2, the CFR circuitry 205 provides the x(n) signal 202, the ACLR profile data 220, and the signal profile data 222 to the DPD circuitry 208. In other examples described in the teachings herein, the transmitter circuitry 108A is implemented without the CFR circuitry 205. In such other examples, the DPD circuitry 208 the x(n) signal 202, the ACLR profile data 220, and the signal profile data 222 directly from the processor circuitry 106A.

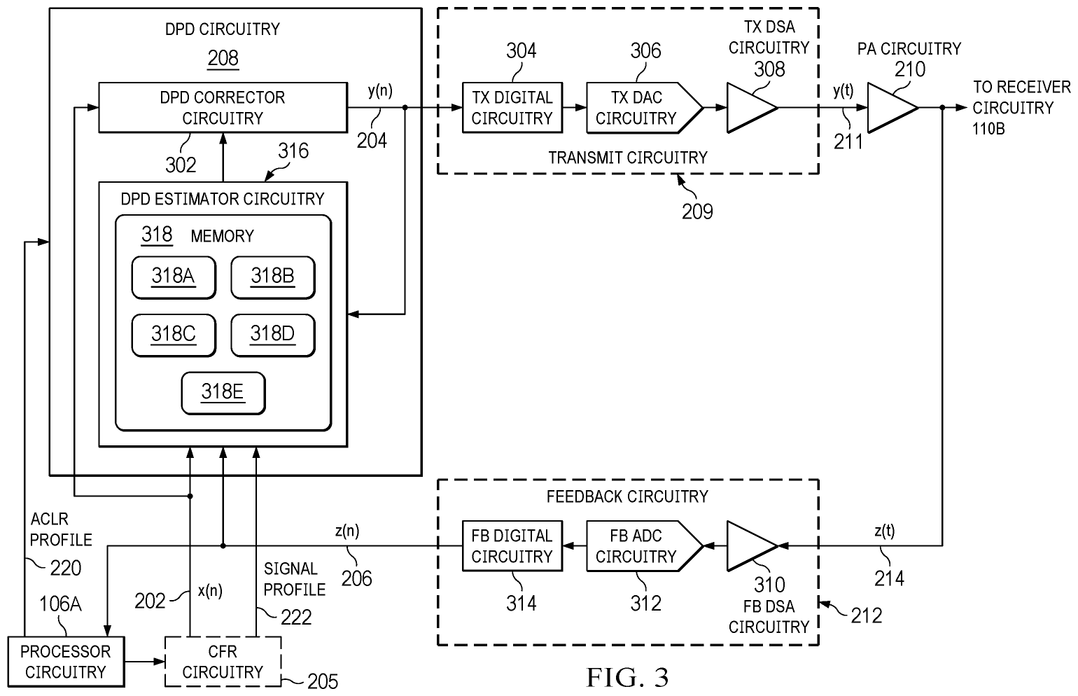

The DPD circuitry 208 uses the x(n) signal 202, the z(n) signal 206, the ACLR profile data 220, and the signal profile data 222 to generate the y(n) signal 204. The y(n) signal 204 is a distorted version of the x(n) signal 202 that can counteract the nonlinearity of the PA circuitry 210 unevenly across frequency, thereby improving performance in situations where the x(n) signal 202 exhibits high power and high bandwidth (e.g., the width of the signal band is relatively large). The DPD circuitry 208 is described further in connection with FIG. 3.

The transmit circuitry 211 prepares the y(n) signal 204 for transmission. To do so, the transmit circuitry 211 performs interpolation, digital to analog conversion, and attenuation operations to produce the analog y(t) signal 211 responsive to the y(n) signal 204. The transmit circuitry 211 is discussed further in connection with FIG. 3.

The example PA circuitry 210 amplifies the y(n) signal 204 to generate an analog output z(t) signal, which is strong enough to sustain the signal attenuation across the wireless medium 104 and contain interpretable data when received at the receiver circuitry 110B. The PA circuitry 210 provides the z(t) signal 214 to an antenna for transmission.

The example feedback circuitry 212 receives a copy of the analog z(t) signal 214 and uses the copy to generate the digital z(n) signal 206. The feedback circuitry 212 also provides the z(n) signal 206 to the DPD circuitry 208. The feedback circuitry 212 and the z(n) signal 206 are described further in connection with FIG. 3.

In general, the various components of the transmitter circuitry 108 may be implemented as hardware, software, or a combination thereof. In some examples, the CFR circuitry 205 and the DPD circuitry 208 are digital circuits, the PA circuitry 210 is an analog circuit, the transmit circuitry 209 includes a combination of analog circuitry and digital circuitry, and the feedback circuitry 212 includes a combination of analog circuitry and digital circuitry. One or more of the various components within the transmitter circuitry 108A may be implemented on the same integrated circuit (IC). In some examples, the CFR circuitry 205 and DPD circuitry 208 are implemented on the same IC. In some examples, the DPD circuitry 208 is implemented on a standalone IC without any other components of the transmitter circuitry 108A.

FIG. 3 is an example block diagram of the DPD circuitry 208 of FIG. 2. FIG. 3 includes the processor circuitry 106A, the CFR circuitry 205, DPD circuitry 208, the transmit circuitry 209, the PA circuitry 210, and the feedback circuitry 212. The DPD circuitry 208 includes example DPD corrector circuitry 302, and example DPD estimator circuitry 316. The DPD estimator circuitry 316 includes example memory 318. The transmit circuitry 209 includes example transmission (TX) digital circuitry 304, example TX digital to analog converter (DAC) circuitry 306, and example TX digital step attenuator (DSA) circuitry 308. The feedback circuitry 212 includes example feedback (FB) DSA circuitry 310, example FB analog to digital converter (ADC) circuitry 312, and example FB digital circuitry 314. Signals used by, generated in, or generated by the DPD circuitry 208 include the x(n) signal 202, the y(n) signal 204, the y(t) signal 211, the z(n) signal 206, the ACLR profile data 220, and the signal profile data 222.

The example DPD corrector circuitry 302 generates the y(n) signal 204 using a DPD equation such as equation (1):

$${y ( n )}_{204} = {\sum }_{r = 1}^{{N}_{T}} {C}_{r} \times {f}_{1} ( x ( n - {l}_{1} ( r ) ) ) \times {f}_{3} ( x ( n - {l}_{3} ( r ) ) ) \times {f}_{2} ( \vert x ( n - {l}_{2} ( r ) ) \vert ) \qquad ( 1 )$$

As used above, l₁(r), l₂(r), and l₃(r) are lag terms that are specific to a particular type of PA circuitry and can be pre-determined and stored before the input signal x(n) 202 is received. Similarly, The values of Cᵣ are coefficients that are estimated by the DPD estimator circuitry 316 as described further below.

Within the transmit circuitry 209, the TX digital circuitry 304 interpolates the y(n) signal 204 to introduce additional data points. The additional data points increase the sample rate of the y(n) signal 204 relative to the sample rate of the x(n) signal 202. The TX digital circuitry 304 allows the DPD corrector circuitry 302 to only sample the signal for pre-distortion when necessary (e.g., at a relatively lower frequency).

The TX DAC circuitry 306 converts the output of the TX digital circuitry 304 from a digital signal to an analog signal. As a result, information transmitted across the wireless medium 104 is encoded continuously across a range of voltages rather than a discrete set of voltages.

The TX DSA circuitry 308 attenuates the output of the TX DAC circuitry 304 to stabilize the output power of the PA circuitry 210. In particular, the TX DSA circuitry 308 attenuates the signal responsive to the gain of the PA circuitry 210, which may change responsive to temperature. The example TX DSA circuitry 308 provides an output, y(t) signal 211, to the example PA circuitry 210. The PA circuitry 210 then amplifies the signal for transmission to the receiver circuitry 110B.

Within the feedback circuitry 212, the FB DSA circuitry 310 receives the analog output z(t) signal 214 from the PA circuitry 210 and attenuates the signal. In some examples, the FB DSA circuitry 310 attenuates the analog output z(t) signal 214 responsive to the operating parameters of the FB ADC circuitry 312.

The FB ADC circuitry 312 converts the attenuated output z(t) signal 214 from an analog signal to a digital signal. The FB digital circuitry 314 then decimates (e.g., removes data points from) the digital signal to produce the feedback signal z(n) signal 206. As a result, z(n) signal 206 can be provided to and interpreted by both the example DPD estimator circuitry 316 and the processor circuitry 106A.

The coefficients Cᵣ within any implementation of equation (1) may not be directly computable because the values may change over time responsive to the contents of the x(n) signal 202 and temperature variations of the PA circuitry 210. The DPD estimator circuitry 316 therefore estimates the values of Cᵣ using equation (2):

$${C}_{r} = {argmin}_{{c}_{r}} {\sum }_{n = 0}^{N - 1} {\vert f ( \{ e [ n ] \} \vert}^{2} \qquad ( 2 )$$

As used in equation 2, N is the number of samples used for estimation. e[n] is an error signal given by equation (3):

$$e [ n ] = {z [ n ]}_{206} - {x [ n ]}_{202} \qquad ( 3 )$$

Finally, ƒ{ } in equation 2 is a shaping function implemented as described in the teachings herein. The shaping function ƒ{ } changes the value of the operand within Σₙ₌₀^{N-1}∥², thereby changing the value of the DPD coefficients Cᵣ. In some examples, the changes to Cᵣ. caused by ƒ{ } are referred to as an application of the shaping function, a shaping of the pre-distortion function, or a medication of the pre-distortion function. The coefficients within equation (2) are not directly computable because the values may change over time responsive to the contents of the x(n) signal 202 and temperature variations of the PA circuitry 210. The computation of the coefficients, therefore, is an iterative process that minimizes the error e(n) between the original input x(n) signal 202 and the digital, decimated, and attenuated output z(n) signal 206. In examples described herein, the DPD corrector circuitry 302 assigns pre-determined values to Cᵣ initially. The DPD estimator circuitry 316 then generates multiple sets of coefficient deltas sequentially. A given set of coefficients delta describe changes to Cᵣ that result in the value of e(n) coming closer to zero. In an example, the DPD corrector circuitry 302 implements equation (4) and the DPD estimator circuitry 316 implements equation (5) as provided:

$${c}_{k} = {c}_{k - 1} + Δ {c}_{k} \qquad ( 4 )$$

$$Δ {c}_{k} = \frac{{( f {\{ H \}}^{H} f \{ H \} )}^{- 1} ( f {\{ H \}}^{H} f \{ E \} )}{{G}_{k}} \qquad ( 5 )$$

In equation (4), Cₖ refers to one of the NL term coefficients Cᵣ (in Eq (1)) at time k, cₖ₋₁ refers to the value of the same coefficient at time k−1, and Δcₖ is a coefficient delta describing how cₖ differs from cₖ₋₁. When the x(n) signal 202 is sampled, the DPD corrector circuitry 302 receives a set of Δcₖ terms from the DPD estimator circuitry 316 and adds the Δcₖ terms to Cᵣ to use in determining the y(n) signal 204.

In equation (5), ƒ{ } is the shaping function of equation 2, Gₖ is the gain of the PA circuitry 210, and E is a vector formed by samples of an error signal e(n). The error signal e(n) describes the difference between the original input x(n) signal 202 and the digital, decimated, and attenuated output z(n) signal 206. Equation (5) also includes H, which is a matrix of equation terms formed by the example DPD estimator circuitry 316. The DPD estimator circuitry 316 uses components of the H matrix to compute the H^{H} H matrix and H^{H} E vector. The H^{H}H matrix refers to a regularized and invertible matrix of equations terms. In some examples, an individual instance of the H^{H} H matrix is referred to as a partial Hermitian matrix. Similarly, the H^{H}E vector refers to the correlation of NL terms (which are in the H matrix) with the error signal (which is represented by the E vector). As used above and herein, the H matrix refers to the set of data used by the example DPD estimator circuitry 316 to compute the H^{H} H and H^{H}E matrices in equation (5).

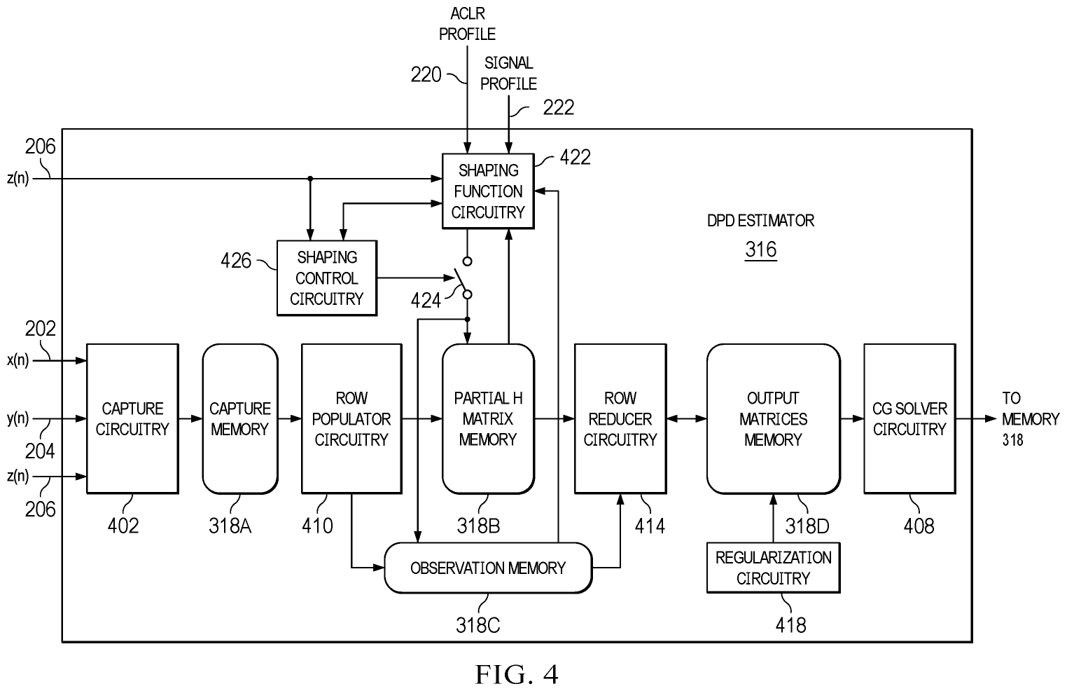

The memory 318 stores data used by the various components of the DPD estimator circuitry 316 to perform operations. In examples described herein, the memory 318 includes various sections, including but not limited to capture memory 318A, partial H matrix memory 318B, observation memory 318C, output matrices memory 318D, and nonlinear (NL) term memory 318E. The DPD estimator circuitry 316 stores different data in each of the sections of the memory 318. For example, pre-determinable lag terms and types of non-linear functions corresponding to a selected implementation of equation (1) are stored within the NL term memory 318E. The contents of the memory 318 are described further in connection with FIG. 4.

The memory 318 may be implemented as any type of memory. For example, the memory 318 includes both volatile memory and non-volatile memory. The volatile memory may be implemented by Synchronous Dynamic Random Access Memory (SDRAM), Dynamic Random Access Memory (DRAM), RAMBUS® Dynamic Random Access Memory (RDRAM®), or any other type of RAM device. The non-volatile memory may be implemented by flash memory or any other desired type of memory device.

In some examples, one or more portions of the memory 318 is implemented as a database. In such examples, the one or more portions of the memory 318 is implemented by any memory, storage device or storage disc for storing data such as, flash memory, magnetic media, optical media, solid state memory, hard drive(s), thumb drive(s), etc. Furthermore, the data stored in the one or more portions of the memory 318 may be in any data format such as, binary data, comma delimited data, tab delimited data, structured query language (SQL) structures, etc. While the memory 318 is illustrated in FIG. 3 as a single device, the memory 318 and any other data storage devices described herein may be implemented by any number or type(s) of memories.

FIG. 4 is a block diagram of an example implementation of the DPD estimator circuitry 316 of FIG. 3 to estimate DPD coefficients. The DPD estimator circuitry 316 of FIG. 4 may be implemented as digital logic circuitry in hardware. The DPD estimator circuitry 316 may also be instantiated (e.g., creating an instance of, bring into being for any length of time, materialize, implement, etc.) by programmable circuitry such as a Central Processor Unit (CPU) executing first instructions. The DPD estimator circuitry 316 may further be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 3 may, thus, be instantiated at the same or different times. Some or all of the circuitry of FIG. 3 may be instantiated, for example, in one or more threads executing concurrently on hardware or in series on hardware. Moreover, in some examples, some or all of the circuitry of FIG. 2 may be implemented by microprocessor circuitry executing instructions or FPGA circuitry performing operations to implement one or more virtual machines or containers.

FIG. 4 shows that the DPD estimator circuitry 316 includes example capture circuitry 402, the capture memory 318A, example row populator circuitry 410, an example partial H matrix memory 318B, the observation memory 318C, example row reducer circuitry 414, the output matrices memory 318D, example regularization circuitry 418, example conjugate gradient (CG) solver circuitry 408 example shaping function circuitry 422, an example switch 424, and example shaping control circuitry 426.

The capture circuitry 402 samples the digital input x(n) signal 202, the pre-distorted y(n) signal 204, and the feedback signal z(n) signal 206. In some examples, the capture circuitry 402 performs captures samples periodically responsive to a clock signal.

The capture circuitry 402 stores the samples in the capture memory 318A. The capture memory 318A may be implemented by any type of memory. While illustrated as an internal component of the DPD estimator circuitry 316 in the example of FIG. 4, in other examples, the capture memory 318A is a component of the example memory 318. In another example, the capture circuitry 402 and capture memory 318A are implemented in digital logic circuitry, which may include one or more synchronous or asynchronous logic devices.

The row populator circuitry 410 stores a threshold number, P, rows of the H matrix within the partial H matrix memory 318B. A given row stored within the partial H matrix memory 318B corresponds to a single instance of time such that an equation in row 1 corresponds to a first sample of the input signal; an equation in row 2 corresponds to a second sample of the input signal; and the second sample occurs after the first sample.

The partial H matrix memory 318B is an incomplete version of the H matrix used in equation (5). The partial H matrix memory 318B may be stored in any type of memory. The partial H matrix memory 318B is illustrated as an internal component of the DPD estimator circuitry 316 in the example of FIG. 4 for simplicity. In examples used above and herein, the partial H matrix memory 318B is a portion the memory 318. In some examples, the DPD estimator circuitry 316 stores the full version (e.g., the complete version) of the H matrix within the memory 318 rather than an incomplete version. In such examples, the amount of data in the memory 318 used to store the full H matrix is greater than the amount of data stored in the partial H matrix memory 318B.

The observation memory 318C stores observation terms populated by the row populator circuitry 410. As used above and herein, observation terms refer to values used by the row reducer circuitry 414 to determine the H^{H}E vector from equation (5). The DPD estimator circuitry 316 also uses the observation terms as individual elements of the Error vector E from equation 5.

The row reducer circuitry 414 receives the row data stored within the partial H matrix memory 318B. The row reducer circuitry 414 performs reduction operations to transform the P rows stored within of the partial H matrix memory 318B into a version of the H^{H}H matrix of equation (5). The row reducer circuitry 414 also receives observation terms from the observation memory 318C and performs reduction operations with the observation terms to form a version of the H^{H}E vector of equation (5).

The output matrices memory 318D stores a single version of an H^{H} H matrix and a single version of an H^{H}E vector of equation (5). In particular, one matrix stored in the output matrices memory 318D is an accumulated version of all previous H^{H} H matrices formed by the row reducer circuitry 414. Similarly, the other vector stored in the output matrices memory 318D is an accumulated version of all operations performed by the row reducer circuitry 414 to compute the H^{H}E vector. The output matrices memory 318D may be implemented by any type of memory. The output matrices memory 318D is illustrated as an internal component of the DPD estimator circuitry 316 in the example of FIG. 4 for simplicity. In examples described above and herein, the output matrices memory 318D is a component of the memory 318.

The regularization circuitry 418 adds regularization terms to the H^{H} H matrix in the output matrices memory 318D. The regularization terms help to increase the rank of the H^{H} H matrix in the example output matrices memory 318D, which enables the CG solver circuitry 408 to invert the H^{H} H matrix as described in equation (5).

The CG solver circuitry 408 receives H^{H}H matrix and H^{H}E vector from the output matrices memory 318D and uses the matrices to compute Δcₖ. The CG solver circuitry 408 may implement any suitable linear equation solver to compute Δcₖ.

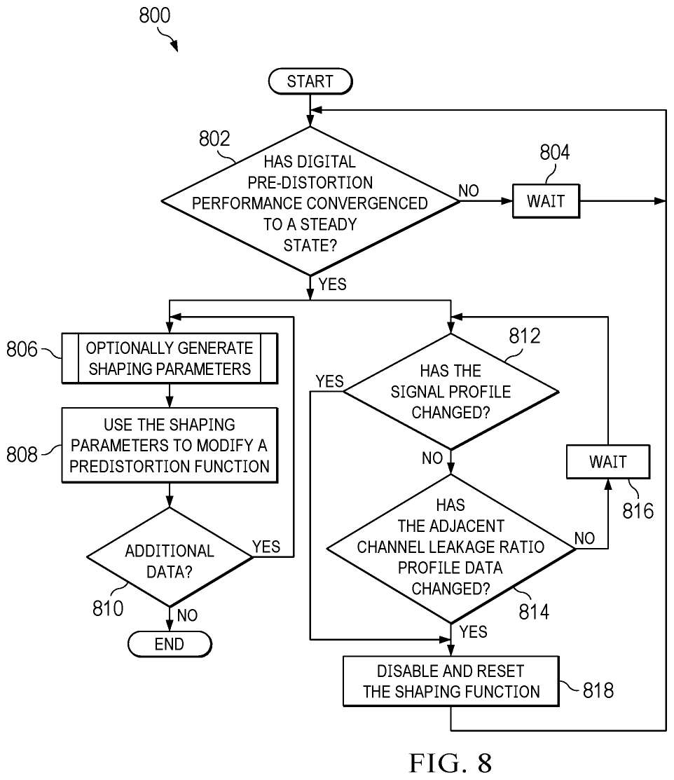

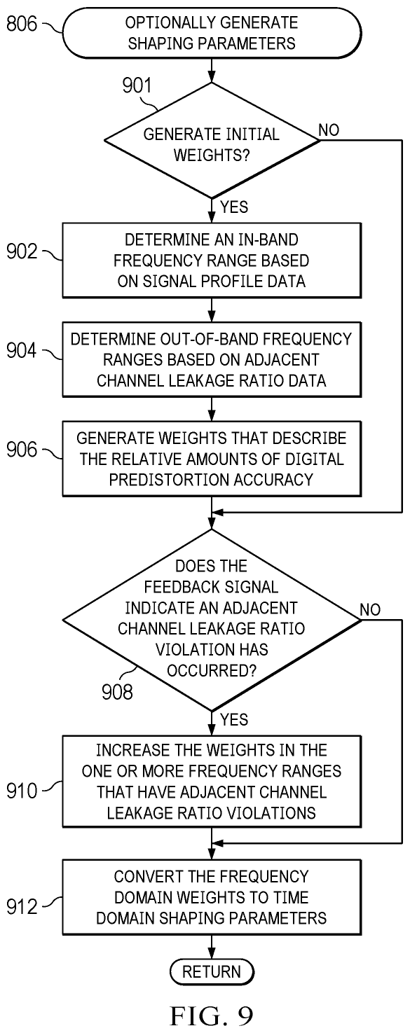

The shaping function circuitry 422 generates and applies the shaping function ƒ{ } to the values of the partial H matrix memory 318B and the observation memory 318C as described in the teachings herein. The shaping function circuitry 422 generates the shaping function responsive to the z(n) signal 206, the ACLR profile data 220, and the signal profile data 222. The shaping function circuitry 422 is described further in connection with 5-9. In some examples, the shaping function circuitry 422 is implemented as digital logic in hardware to perform operations such as those represented by the flowchart(s) of FIGS. 8 and 9. In other examples, the shaping function circuitry 422 is instantiated by programmable circuitry executing shaping function instructions to perform operations such as those represented by the flowchart(s) of FIGS. 8 and 9.

The shaping control circuitry 426 enables and disables the generation and application of the shaping function at various times. In the example of FIG. 4, the shaping control circuitry 426 enables the shaping function by closing the switch 424. Similarly, the shaping control circuitry 426 disables the shaping function by opening the switch 424. The shaping control circuitry 426 determines when to enable or disable the shaping function responsive to the z(n) signal 206 and a detection signal provided by the shaping function circuitry 422. In some examples, the shaping control circuitry 426 is implemented as digital logic in hardware to perform operations such as those represented by the flowchart(s) of FIGS. 8 and 9. In other examples, the shaping control circuitry 426 is instantiated by programmable circuitry executing shaping function instructions to perform operations such as those represented by the flowchart(s) of FIGS. 8 and 9.

When enabled, the shaping function circuitry 422 applies the shaping function ƒ{ } by changing values within the partial H matrix memory 318B and the observation memory 318C. The changes in the partial H matrix memory 318B and the observation memory 318C cause the CG solver circuitry 408 to produce different values of Δcₖ than it would have if the shaping function was not applied. The DPD corrector circuitry 302 uses the different values of Δcₖ to change the values of Cᵣ such that the pre-distortion in the y(n) signal 204 is more accurate in some frequency bands than others. Accordingly, the shaping function circuitry 422 increases the effectiveness of the DPD circuitry 208 in in situations where the x(n) signal 202 exhibits high power and high bandwidth.

The shaping control circuitry 426 provides the option to keep the shaping function disabled until data within the z(n) signal 206 indicates that DPD convergence has reached steady state. DPD convergence reaches steady state when the rate of change to the error signal e(n) has decreased below a threshold value (which generally occurs when the value of e(n) is near 0). Upon enabling the shaping function, the shaping control circuitry 426 re-disables the shaping function if the shaping function circuitry 422 indicates a change has occurred to the ACLR profile 220 or the signal profile data 222. Accordingly, the shaping control circuitry 426 reduces the computational resource usage of the DPD estimator circuitry 316 by only enabling the shaping function when its application is required for additional performance improvements (e.g., to move e(n) closer to 0).

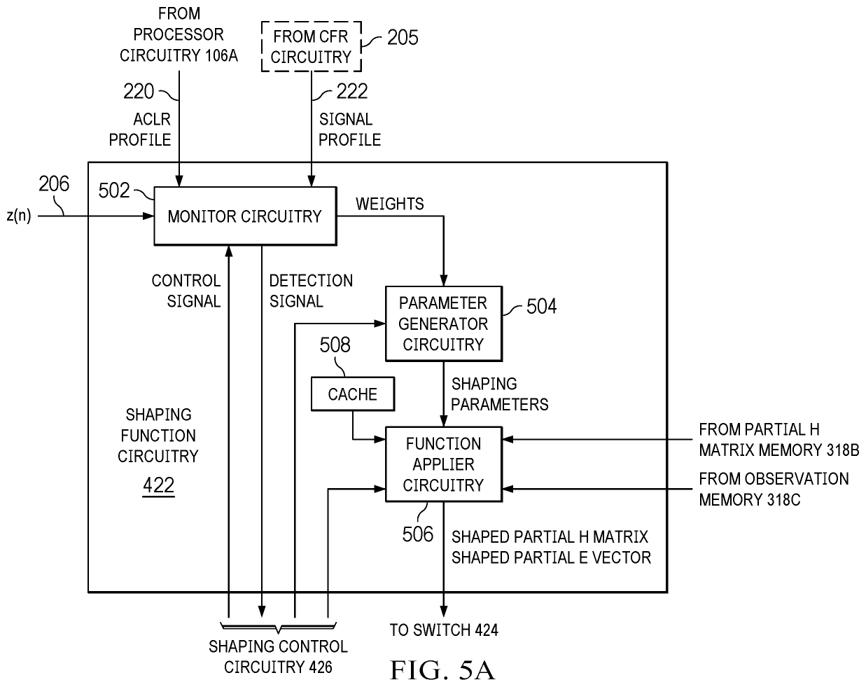

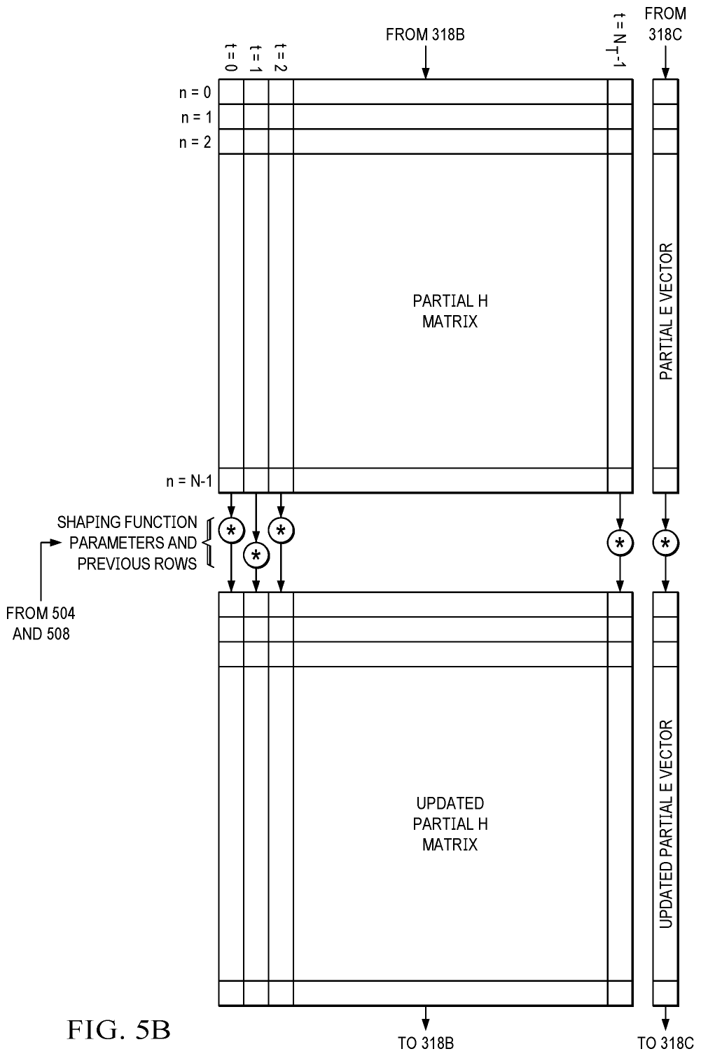

FIG. 5A is a block diagram of an example implementation of the shaping function circuitry 422 FIG. 4. The shaping function circuitry 422 includes example monitor circuitry 502, example parameter generator circuitry 504, example function applier circuitry 506, and an example cache 508.

The monitor circuitry 502 receives a control signal from the shaping control circuitry 426. The control signal enables or disables the monitor circuitry 502 to perform operations. When enabled, the monitor circuitry 502 uses the ACLR profile data 220 and the signal profile data 222 to determine an initial set of weights. A weight refers to a value that quantifies the relative accuracy of pre-distortion to occur in a given range of frequencies where the z(t) signal 214 is transmitted. The weights are relative values such that, if a first frequency range has a larger weight than a second frequency range, the pre-distortion in the first frequency range of the subsequent transmitted signal is more accurate than the pre-distortion in the second frequency range.

In general, the monitor circuitry 502 generates weights responsive to instances where a signal is transmitted within the range of out-of-band frequencies. The monitor circuitry 502 may predict future instances of such noise emissions using the ACLR profile data 220. The monitor circuitry 502 may also observe past instances of the noise emissions using the z(n) signal 206.

In some examples, the monitor circuitry 502 assigns weights based on the ACLR profile data 220 and the signal profile data 222 in combination with other factors. Such other factors may include but are not limited to the suppression of intermodulation components (e.g., in New Radio (NR) signals). Weights are described further in connection with FIG. 6.

When enabled, the monitor circuitry 502 also monitors the z(n) signal 206, the ACLR profile data 220, and the signal profile data 222 for changes. The monitor circuitry 502 then performs various operations responsive to the type of change. For example, the monitor circuitry 502 may adjust one or more weights in response to a change in the z(n) signal 206 indicating that the z(t) signal 214 was transmitted with more power in an out-of-band frequency range than anticipated.

As another example, the monitor circuitry 502 also sends a detection signal to the shaping control circuitry 426 when either the ACLR profile data 220 and signal profile data 222 changes, thereby causing the shaping control circuitry 426 to disable the generation and application of the shaping function. The shaping control circuitry 426 stops the shaping function in response to receiving a detection signal because the weights generated by the monitor circuitry 502 are formed in part by which frequency ranges the processor circuitry 106A expects to transmit the x(n) signal 202 (as indicated in the signal profile data 222) and which frequency ranges are predicted to have noise as a result of the transmission (as indicated by the ACLR profile data 220). Accordingly, if the processor circuitry 106A changes the frequency or power at which the x(n) signal 202 is transmitted, the current weights do not reflect such a change and the shaping function becomes inapplicable. Furthermore, a change in the signal profile data 222 as described above may also cause a change in the ACLR profile 220 because the CFR circuitry 205 (or the processor circuitry 106A) predicts the characteristics of electromagnetic noise responsive to the characteristics of the signal to be transmitted. The signal profile data 222 and the ACLR profile data 220 may change at any time and for any reason.

When enabled by the shaping control circuitry 426, the parameter generator circuitry 504 generates shaping parameters responsive to the weights. The operations performed by the parameter generator circuitry 504 may be characterized as a conversion because the weights are values that correspond to the frequency domain (e.g., the value of the weights change as z(n) 206 changes across frequency) and the shaping parameters are values that correspond to the time domain (e.g., the value of shaping parameters change as z(n) 206 changes across time). The parameter generator circuitry 504 may use any suitable technique to convert from the frequency domain to the time domain, including but not limited to Least-Squares Spectral Analysis (LSSA). The shaping parameters may be collectively referred to as a shaping function because there exists a mathematical function to describe how the shaping parameters are applied during DPD estimation. While the value of the shaping parameters change across time, the number of shaping parameters is fixed in some examples to match the number of NL terms (e.g., number of columns) in the H matrix and E vector.

The function applier circuitry 506 uses the shaping parameters to modify the partial H matrix and the partial E vector using convolution operations. A convolution operation on a given row of the full H matrix requires an amount of data from previous rows of the previous rows. This previous rows data are not available in the partial H matrix memory 318B, which stores the current version of the partial H matrix. Accordingly, the function applier circuitry 506 stores a copy of the partial H matrix in the cache 508 after applying modifications. When performing future operations, the function applier circuitry 506 then accesses the cache 508 to use the previous version of the partial H matrix as input data the convolution operations. Similarly, the cache 508 stores previous versions of the partial E vector, which the function applier circuitry 506 uses to perform convolution operations on the current version of the partial E vector stored in observation memory.

The cache 508 acts as a first in first out buffer (FIFO) in that the function applier circuitry 506 overwrites the oldest version of the partial H matrix and partial E vector in the cache 508 in order to store a new version of the partial H matrix and partial E vector. In examples where the DPD estimator circuitry 316 stores full versions of the H matrix and E vector within the memory 318, the input data required to perform the convolution operations is already present in the memory 318 and the shaping function circuitry 422 can be implemented without the cache 508.

FIG. 5B is an example of operations performed by the shaping function circuitry 422 of FIG. 4. FIG. 5B includes an original version and an updated version of the partial H matrix. The partial H matrix includes one row per sample n of the feedback signal z(n) 206. The partial H matrix also includes one column per term used in the pre-distortion function. Accordingly, the total number of columns is N_{T} as used in equation (1).

When enabled by the shaping control circuitry 426, the function applier circuitry 506 applies the shaping parameters by editing entries within the partial H matrix memory 318B and observation memory 318C. To do so, the function applier circuitry 506 uses the shaping parameters to form a linear filter and applies the filter, using a convolution operation, to individual columns of the partial H matrix and corresponding entries in the partial error vector E. By doing so, the function applier circuitry 506 transforms the original partial H matrix into the updated partial H matrix and the original partial E vector into the updated partial E vector as shown in FIG. 5B. In other examples, the function applier circuitry 506 applies the shaping parameters to the partial H matrix and partial E vector using a different technique instead of a linear filter.

An individual column of the partial H matrix corresponds to an individual nonlinear term of the pre-distortion function of equation 1. Upon accessing a given nonlinear term, the function applier circuitry 506 modifies the elements in the partial H matrix memory 318B using the shaping parameters as a linear filter as described above. The modified elements are considered an application of the shaping function because they result in different values of Cᵣ in equation 1. The modified elements also cause the generation of a modified pre-distortion function as described above. As used in FIG. 5 and examples herein, the result of the operations performed by the function applier circuitry may be referred to a shaped partial H matrix or an updated partial H matrix, an updated E vector or a shaped E vector.

In the example of FIGS. 5A and 5B, the function applier circuitry 506 uses the same set of shaping parameters to modify both the partial H matrix and the partial E vector. In other examples, the monitor circuitry 502 may generate two different sets of weights for a given set of inputs (e.g., the ACLR profile data 220, signal profile data 222, and feedback signal z(n) 206). In such examples, the parameter generator circuitry 504 generates two sets of shaping parameters, thereby causing the function applier circuitry 506 to apply one set of shaping parameters to the partial H matrix and the other set of shaping parameters to the partial E vector.

FIG. 6 are graphs illustrating example operations performed by the shaping function circuitry of FIG. 4. FIG. 6 includes example graphs 602, 614, and 616. Graph 602 includes an example signal band 604 and example ACLR bands 606, 608, 610, and 612.

The graph 602 is an example of the signal profile data 222 and corresponding ACLR profile data 220. The graph 602 displays frequency on its x axis (measured in MHz) and power spectral density on its y axis. Power spectral density describes the distribution of power present per unit frequency. In the examples herein, power spectral density is measured in dBc/Hz (decibels relative to a carrier in a 1 Hertz bandwidth), which is generally annotated as “dB” for simplicity.

In the example of FIG. 4, the graph 602 shows that the signal band 604 and ACLR bands 606-612 are all 100 MHz wide (e.g., have a bandwidth of 100 MHz). In other examples, one or more of the ACLR bands 606-612 have different bandwidths. Furthermore, in some examples, the bandwidth of the signal band 604 is different from one or more of the of the ACLR bands 606-612.

The graph 602 also shows that all frequencies within a continuous range of 500 MHz fall within one of the signal band 604 or ACLR bands 606-612. In other examples, the total width of the signal and ACLR bands is different. The difference may occur because, in some examples, one or more of the signal bands 604 and the ACLR bands 606-612 are discontinuous (e.g., one or more gaps exist between or within the ACLR bands 606-612 or the signal band 604). In general, the signal band 604 is approximately centered within the ACLR bands 606-612 because the transmitted signal within the signal band 604 is the source of the electromagnetic noise within the ACLR bands 606-612.

The graph 602 further shows that the power spectral densities of the ACLR bands are equal to one another. In other examples, the power spectral densities of some ACLR bands is different than others. For instance, some signal bands may lead to a prediction that electromagnetic interference is like to occur in a normal distribution centered on the signal band. A normal distribution may also be referred to as a bell curve or a Gaussian curve. In such normal distribution examples, ACLR bands that are closer to the signal band have a larger power spectral density than ACLR bands that are further away from the signal band (where distance refers to a measure of frequency). In some examples, electromagnetic interference may be referred to as emissions or as noise.

The graphs 614 and 616 are both example implementations of how the monitor circuitry 502 assigns weights across frequency. Both graphs 614 and 616 include one weight value per frequency band on the graph 602. In other examples, the monitor circuitry 502 may assign any number of weights per signal band or ACLR band. To do so, the monitor circuitry 502 subdivides the given frequency band into smaller ranges of frequencies and assigns weights to the respective smaller ranges.

In general, the weights may use any numbering scheme to quantify relative importance. In examples described herein, the weights may be any floating-point value between (0.0, 1.0]. The value 0.0 is excluded from the possible weight values because the pre-distortion function is a continuous function. Therefore, the DPD corrector circuitry 302 may have to perform at least a nonzero amount of distortion to every frequency within a continuous range surrounding x(n) 202.

In graph 614, the ACLR bands 606-612 receive weights of 1.00 while the signal band 604 receives a weight of 0.1. Accordingly, if the monitor circuitry 502 were to provide the weights in graph 614 to the parameter generator circuitry 504, a shaping function would modify the partial H matrix memory 318B such that the DPD coefficients corresponding to ACLR bands 606-612 are 10 times more accurate than the DPD coefficients corresponding to the signal band 604. Such weightage may be appropriate in situations where the power spectral density of the various ACLR bands is approximately equal, as shown in graph 602.

In graph 616, the signal band 604 receives a weight of 0.10, the ACLR bands 606 and 612 receive a weight 0.30, and the ACLR bands 608 and 610 receive a weight of 1.0. Accordingly, if the monitor circuitry 502 were to provide the weights in graph 616 to the parameter generator circuitry 504, the DPD corrector circuitry 302 would ultimately cause the pre-distortion accuracy of the ACLR bands 608 and 610 to be greater than the pre-distortion accuracy of the ACLR bands 606 and 612. The DPD corrector circuitry 302 of such examples would also cause the pre-distortion accuracy to the ACLR bands 606 and 612 to be greater than the pre-distortion accuracy of the signal band. Such weightage may be beneficial when performance is to be prioritized in frequency bands near the signal band (e.g., in a Normal Distribution as described above). In other examples, the monitor circuitry 502 generates different weights besides those shown in graphs 614 and 616.

FIG. 7 are additional graphs illustrating example operations performed by the shaping function circuitry of FIG. 4. FIG. 7 includes the example graphs 702 and 704.

The graph 702 is an example of a transmitted signal z(t) 214 when represented in the frequency domain and when a shaping function is not applied. The graph 702 describes a situation where the signal band is high bandwidth (e.g., 200 MHz).

As the amount of noise within a given frequency range increases, the ability of a receiver device to effectively interpret data within the frequency range decreases. As a result, telecommunication companies develop and enforce various standards that require certain EVM performance of the transmitted signal. To meet the EVM performance requirements, designers and manufacturers generally maintain internal requirements that the Signal to Noise Ratio (SnR) of the signal band remain above a threshold value (e.g., y dB as described in connection with FIG. 7). In the example of graph 702, the signal band has an SnR of (y+5) dB and satisfies the EVM requirement.

Transmitter devices used commercially are generally required to satisfy both the EVM requirements for in-band frequency ranges and the ACLR standards for out-of-frequency ranges. To prevent electromagnetic interference causing cross talk or other unexpected behavior, ACLR standards generally require that the ACLR of the worst performing out-of-band range be satisfy a threshold. For example, the threshold is satisfied in FIG. 7 when the ACLR of the worst performing out-of-band range is below x dB. The value x dB may be either positive or negative. The sign of the ACLR measurement is responsive to which values (e.g., the ACLR band power value and the signal band power value) are placed in the numerator and denominator of a measurement operation. In the example graph 702, the ACLR bands adjacent to the signal band have an ACLR of x dB. Accordingly, even though ACLR bands further from the signal band satisfy the ACLR requirement (because (x−5) dB<x dB), and even though the signal band satisfies the EVM requirement, a transmitter device that performs as shown in graph 702 may have little to no ability to operate in such high bandwidth environments.

The graph 702 shows a first example performance of the DPD circuitry 208, during which a shaping function was never applied. When the shaping function circuitry 422 does apply a shaping function, the DPD circuitry 208 can receive the same inputs as provided in the first example and instead perform as described in graph 704.

In graph 704, the ACLR of the frequency bands adjacent to the signal band have improved to (x−3) dB. To provide such improvement, the shaping function circuitry 422 applies a shaping function that causes less accurate pre-distortion in the signal band and furthest ACLR bands. As a result, the example of graph 704 shows the SnR of the signal band decreases to (y+3) dB and the ACLR bands of the furthest frequency bands increase to (x−4) dB. Notably, however, the foregoing EVM requirement is still met in graph 704 because (y+3) dB>y dB. Furthermore, the foregoing ACLR specification is now met in graph 704 because (x−3) dB<x dB. As a result, a transmitter device that performs according to graph 704 could be used more in high bandwidth and high-power situations than a device that performs according to graph 702. More generally, the shaping function circuitry 422 designs and applies the shaping function such that any corresponding decrease in performance is: a) negligible when compared to the scale of improvements in performance and b) located in regions of the frequency spectrum where such decreases are tolerable.

As an additional example, empirical testing was performed on power amplifier circuitry having a rated output power of 31 decibel-milliwatts (dBm) and supported frequency band from 2300 MHz-2690 MHz. In the testing, the power amplifier transmitted two New Radio (NR) signals at 100 MHz with 8.5 dB Peak-to-Average Ratio (PAR). Such empirical testing showed that, when the shaping function disabled, the power amplifier could transmit the signals with a lowest ACLR of −48.1 dB and an EVM of 1.80%. When the shaping function was then enabled, the power amplifier could transmit the signals with a lowest ACLR of −49.0 dB and an EVM of 1.80%. Accordingly, examples performed with empirical testing observed approximately 0.9 dB improvement in ACLR without notable degradation to the EVM.

FIG. 8 is a flowchart representative of example machine-readable instructions or example operations 800 that may be executed, instantiated, or performed by programmable circuitry to apply a shaping function for digital pre-distortion. In examples described herein, ACLR is measured with signal power in the numerator such that larger dB values indicate higher quality.

The machine-readable instructions or operations 800 of FIG. 8 begin when the shaping control circuitry 426 determines whether the DPD performance has converged to a steady state. (Block 802). When the transmitter circuitry 108A first begins to transmit a signal, the DPD estimator circuitry 316 attempts to estimate DPD coefficients with little to no data in the z(n) signal 206. Accordingly, the DPD estimator circuitry 316 may provide relatively inaccurate values for C_{R} as shown in equation 2 (or may not provide any values for C_{R}), the DPD corrector circuitry 302 applies a relatively inaccurate pre-distortion function, and the ACLR measurements are relatively poor. However, as more data is provided, the row populator circuitry 410, the row reducer circuitry 414, the regularization circuitry 418, and the CG solver circuitry 408 are able to produce more accurate values for C_{R}. Accordingly, the ACLR measurements (and more generally, DPD performance) begin to increase in quality as the time progresses following an initial transmission.

The logic of block 802 and FIG. 8 are part of one example implementation of the DPD estimator circuitry 316. In other examples, the shaping control 426 enables the shaping function circuitry 422 before DPD performance has converged on a steady state.

The performance of the DPD circuitry in U.S. application Ser. No. 18/129,589 can improve the ACLR to a threshold value relatively quickly (e.g., 45 dB ACLR may be achieved after approximately three to five updates to the value of Cᵣ). In some examples, an update to the value of Cᵣ and subsequent application of equation (1) is referred to as a DPD iteration. Past the threshold value, the improvement of the DPD circuitry in U.S. application Ser. No. 18/129,589 slows down (e.g., improvement from 45 dB to approximately 50 dB may require an additional five to seven DPD iterations). Accordingly, DPD performance is considered to have converged on a steady state once the ACLR meets a threshold value.

Notably, the use of the shaping function circuitry 422 has little to no effect on the rate at which DPD performance converges on a steady state. Accordingly, the DPD circuitry 208 described in the teachings herein may take approximately three to five DPD iterations reach 45 dB ACLR, regardless of whether the shaping function circuitry 422 is enabled or disabled. Therefore, when the DPD performance has not converged to a steady state (Block 802: No), the shaping control circuitry 426 waits (Block 804) with the switch 424 in the open position (e.g., with the application and generation of the shaping function being disabled). Such waiting reduces computational usage and saves power compared to a technique that enables the shaping function circuitry 422 before the DPD performance has converged to a steady state. After an amount of time, control returns to block 802 where the shaping control circuitry 426 checks again for the DPD convergence to a steady state.

If DPD performance has converged to a steady state (Block 802: Yes), the rate of improvement has slowed such that the use of a shaping function is justified for the aid it provides in achieving additional performance gains. Therefore, the shaping function circuitry 422 optionally generates shaping parameters. (Block 806). In the examples above, the shaping control circuitry 426 sends an enable signal to the monitor circuitry and closes the switch 424 to permit the generation and application of the shaping function, respectively. In other examples, the shaping control circuitry 426 enables the generation and application of the shaping function through one or more different techniques. The shaping parameters generated at block 806 are responsive to weight values that describe the relative accuracy of pre-distortion to be applied to the various frequency ranges. The shaping function circuitry 422 optionally implements block 806 because in examples where the ACLR profile has not changed, the signal profile has not changed, and no ACLR violations have occurred since weights were last generated, there is no need to update to the weights. Therefore, the shaping function circuitry 422 may implement block 806 in a subset of iterations of the loop shown in FIG. 8. Block 806 is described further in connection with FIG. 9.

The function applier circuitry 506 within the shaping function circuitry 422 uses the shaping parameters to modify a pre-distortion function. (Block 808). In the examples described herein, the function applier circuitry 506 uses the shaping parameters to form a linear filter that edits individual NL terms of a DPD equation stored in individual columns of the partial H matrix. Similarly, the function applier circuitry 506 also uses the shaping parameters to edit specific elements within the error vector E stored in the observation memory 318C. In other examples where data corresponding to NL terms are not stored in a partial H matrix, the function applier circuitry 506 uses a different technique to modify a pre-distortion function using the shaping parameters. In some examples, the use of such shaping parameters to modify a pre-distortion function is referred to as the application of a shaping function.

The shaping function circuitry 422 determines whether there is additional data within z(n) 206. (Block 810). If there is additional data within z(n) 206 (Block 810: Yes), control returns to block 806 where the shaping function circuitry 422 generates additional shaping parameters responsive to the additional z(n) 206 samples. In some examples, the shaping function circuitry 422 changes the values of the shaping parameters in subsequent iterations responsive to changes to the value of z(n) 206. If no additional data is present within z(n) 206 (Block 810: No), the machine-readable instructions or operations 800 end. Additional data may no longer be available in z(n) 206 for any number of reasons, including but not limited to the device 102A stopping transmission or powering off.

If DPD performance has converged to a steady state (Block 802: Yes), the monitor circuitry 502 determines whether the signal profile data 222 has changed. (Block 812). The signal profile data 222 may change for any reason, including but not limited to dynamic adjustments of the signal profile data 222 responsive to usage of the device 102A. For example, to save power, a base-station device may choose to reduce the signal power and bandwidth of a transmitted signal when the number of connected users is relatively low (e.g., at night). If the signal profile data 222 has changed (Block 812: Yes), control proceeds to block 818.

If the signal profile data 222 has not changed (Block 812: No), the monitor circuitry 502 determines whether the ACLR profile data 220 has changed. (Block 814). In some examples, a change in the signal profile data 222 as described also causes a change in the ACLR profile data 220. ACLR profile data 220 may change due to time or temperature variations corresponding to the PA circuitry 210.

If the ACLR profile data 220 has not changed (Block 814: No), the monitor circuitry 502 waits for an amount of time (Block 816) before control returns to block 802 and the monitor circuitry 502 performs an additional check of the signal profile data 222.

If the signal profile data 222 has changed (Block 812: Yes) or the ACLR profile data 220 has changed (Block 814: Yes), the shaping control circuitry 426 disables and resets the shaping function. (Block 818). In some examples, the shaping control circuitry 426 determines the signal profile or the ACLR profile has changed responsive to receiving a detection signal from the monitor circuitry 502. The shaping control circuitry 426 disables the generation of the shaping function by sending a control signal to the components of the shaping function circuitry 422 (e.g., the monitor circuitry 502, the parameter generator circuitry 504, and the function applier circuitry 506), thereby stopping subsequent generation of additional weight values and subsequent conversion from weight values to shaping parameters. In some examples, the shaping control circuitry disables the application of the shaping function by opening the switch 424.

The shaping control circuitry 426 also resets the shaping function at block 818. Reset operations may include, but are not limited to, removing previous versions of weight values from a local memory of the shaping function circuitry 422, removing previous versions of matrix elements stored in the partial H matrix memory 318B, etc. Control returns to block 802 after block 818, where the shaping control circuitry 426 checks to see if DPD performance is still at a steady state. Once DPD performance has reached a steady state on a subsequent iteration of block 802, the shaping function circuitry 422 begins generating different weight values from those formed in previous iterations of block 806. The different weight values ultimately lead to the DPD corrector circuitry 302 applying a different modification to x(n) 202 than it otherwise would have.

Once DPD performance has converged to a steady state (Block 802: Yes), the DPD estimator circuitry 316 executes blocks 812-818 in parallel with blocks 806-810. Accordingly, while generating and applying the shaping function, the DPD estimator circuitry 316 also continually checks to confirm said shaping function remains applicable.

FIG. 9 is a flowchart representative of example machine-readable instructions for example operations that may be executed, instantiated, or performed using programmable circuitry to generate shaping parameters as described in connection with FIG. 7. In particular, the flowchart of FIG. 9 is an example implementation of block 806 of FIG. 8.

Execution of block 806 begins when the monitor circuitry 502 determines whether to generate initial weights. (Block 901). The monitor circuitry 502 may generate initial weights responsive to the beginning of a transmission, or responsive to the shaping function being disabled and reset at block 808. Similarly, the monitor circuitry 502 does not generate initial weights if a set of weights were already generated before the current iteration of block 806 but after the latest change to the ACLR profile data 220 or signal profile data 222. If the monitor circuitry 502 does not generate initial weights (Block 901: No), control proceeds to block 908.

If the monitor circuitry 502 does generate initial weights (Block 901: Yes), The monitor circuitry 502 determines an in-band frequency range responsive to signal profile data. (Block 902). The signal profile data 222 refers to any data that describes the location(s) of the center frequency and bandwidth(s) of signal band(s). In some examples, the monitor circuitry 502 obtains the signal profile data 222 from CFR circuitry 205, which uses the information to perform Peak-Cancelling CFR operations. In other examples, the device 102A does not include the CFR circuitry 205. In such examples, the monitor circuitry 502 obtains the signal profile data 222 from the processor circuitry 106A. In some examples, the in-band frequency range is referred to as a signal band.

The monitor circuitry 502 determines out-of-band frequency ranges responsive to ACLR profile data. (Block 904). In some examples, the monitor circuitry 502 obtains the ACLR profile data 220 from the processor circuitry 106A responsive to predictions about electromagnetic interference characteristics. The ACLR profile data 220 refers to any data that describes the location(s) of the center frequency and bandwidth(s) of ACLR band(s).

The monitor circuitry 502 generates weights that describe the relative accuracy of digital pre-distortion to occur within the frequency ranges. (Block 906). The monitor circuitry 502 determines the values of the weights based on the signal band, the ACLR bands, and any number of other factors (e.g., intermodulation components, the type(s) of signals being transmitted, the type and function of the device 102A implementing the monitor circuitry 502, etc.). Accordingly, the values of the weights may vary based on the particular use case. In the examples of FIG. 6, the monitor circuitry 502 applies larger weight values to the ACLR bands than the signal band so that pre-distortion occurs more accurately in the ACLR bands. In other examples, the monitor circuitry 502 applies larger weight values to the signal band and smaller weights to ACLR bands that are further away.

After block 906, or if the monitor circuitry 502 does not generate initial weights (Block 901: No), the monitor circuitry 502 determines whether the feedback signal z(n) 206 indicates an ACLR violation has occurred. (Block 908). As used herein, an ACLR violation refers to data indicates the transmitted signal z(t) 214 is not meeting ACLR emission standards (e.g., that all frequency bands encapsulating and surrounding the transmitted signal have ACLR measurements less than a threshold value, as described above in connection with FIG. 7). To perform such a determination, the monitor circuitry 502 converts the time-domain samples of z(n) 206 into frequency domain measurements (using, e.g., a Fourier transform) and then measures ACLR using the frequency domain measurements. By continually checking for ACLR violations at block 908 whenever additional z(n) 206 data is present (Block 810: Yes), the shaping function circuitry 422 can iteratively increase the performance of the DPD estimator circuitry 316 by adjusting weights where needed. If z(n) 206 indicates an ACLR violation has not occurred, (Block 908: No), control proceeds to block 912.

If z(n) 206 indicates an ACLR violation has occurred, (Block 908: Yes), the monitor circuitry 502 increases the weights in the one or more frequency ranges that have ACLR violations. (Block 910). By increasing a weight value, the monitor circuitry 502 causes a different shaping function to be applied to the partial H matrix memory 318B, thereby causing the DPD corrector circuitry 302 to apply a different pre-distortion function to x(n) 202. That is, the operations of block 910 pre-distortion to occur more accurately in the frequency ranges with ACLR violations than would otherwise have occurred. The additional pre-distortion in the specific frequency ranges increases the likelihood of counteracting nonlinearity in said frequency ranges, thereby decreasing the likelihood of ACLR violations occurring in subsequent transmissions.

In some examples, increasing the pre-distortion in a first frequency range (as caused by the operations of block 910) causes less accurate pre-distortion in a second frequency range, and therefore additional noise, to occur in a second frequency range of the transmitted signal. However, industry standards permit a nonuniform amount of noise to exist in the frequency bands that encapsulate and surround a transmitted signal. For example, industry standards for noise are generally looser (e.g., permit more noise) in the signal band and stricter in surrounding ACLR bands (e.g., permit less noise). The different restrictions exist because the expected signal (e.g., x(n) 202) is the dominant source of electromagnetic energy in the signal band, so the signal band can survive a comparatively larger amount of noise than ACLR bands without notable performance issues. Accordingly, the monitor circuitry 502 can increase the weight in given frequency bands block 910 (thereby improving performance of the given frequency bands) in a manner such that any resulting decreases in performance from other frequency bands are negligible.

After implementing block 910, or if z(n) 206 indicates an ACLR violation has not occurred, (Block 908: No), the parameter generator circuitry 504 converts the frequency domain weights to time domain shaping parameters. (Block 912). The parameter generator circuitry 504 may use any suitable technique to perform the conversion operations, including but not limited to Least Squares. The machine-readable instructions or operations 800 return to block 808 after block 912.

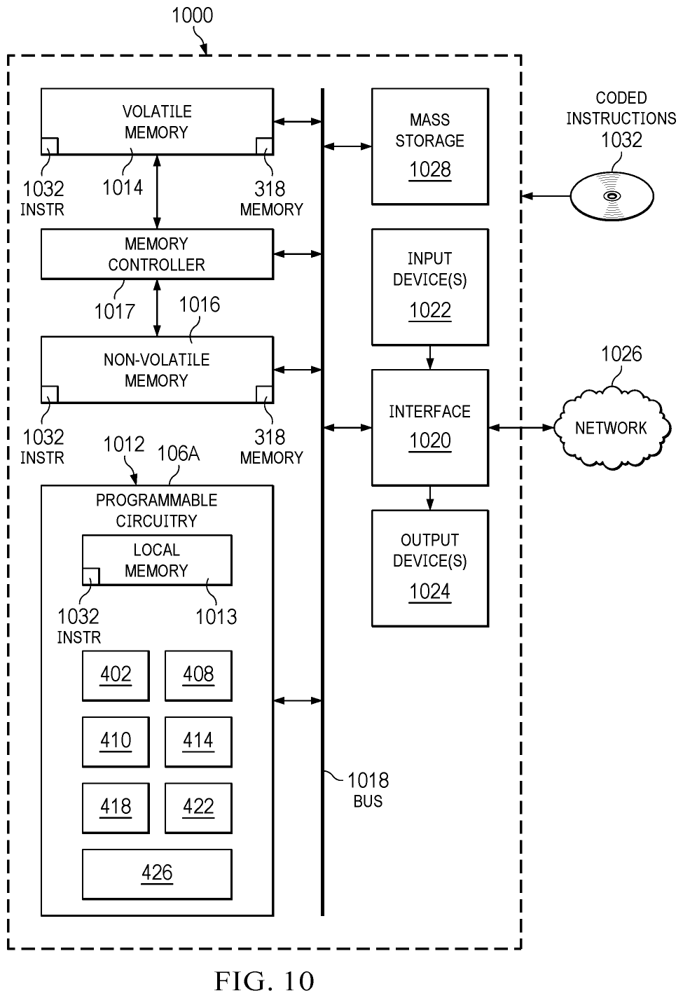

FIG. 10 is a block diagram of an example programmable circuitry platform 1000 structured to execute or instantiate the example machine-readable instructions or the example operations of FIGS. 8 and 9 to implement the DPD estimator circuitry 316 of FIG. 3. The programmable circuitry platform 1000 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, or microcontrollers from any desired family or manufacturer. The programmable circuitry 1012 may be implemented by one or more semiconductor based (e.g., silicon based) devices. In this example, the programmable circuitry 1012 implements the capture circuitry 402, the CG solver circuitry 408, the row populator circuitry 410, the row reducer circuitry 414, the regularization circuitry 418, the shaping function circuitry 422, the shaping control circuitry 426. In some examples, the programmable circuitry 1012 also implements the processor circuitry 106A.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by Synchronous Dynamic Random Access Memory (SDRAM), Dynamic Random Access Memory (DRAM), RAMBUS® Dynamic Random Access Memory (RDRAM®), or any other type of RAM device. The non-volatile memory 1016 may be implemented by flash memory or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016. In this example, the main memory 1014, 1016 implements the memory 318.

The programmable circuitry platform 1000 of the illustrated example also includes interface circuitry 1020. The interface circuitry 1020 may be implemented by consistent with any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1022 are connected to the interface circuitry 1020. The input device(s) 1022 permit(s) a user (e.g., a human user, a machine user, etc.) to enter data or commands into the programmable circuitry 1012. The input device(s) 1022 can be implemented by, for example, an audio sensor, a microphone, a camera (still or video), a keyboard, a button, a mouse, a touchscreen, a trackpad, a trackball, an isopoint device, or a voice recognition system.

One or more output devices 1024 are also connected to the interface circuitry 1020 of the illustrated example. The output device(s) 1024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1020 of the illustrated example, thus, generally includes a graphics driver card, a graphics driver chip, or graphics processor circuitry such as a GPU.

The interface circuitry 1020 of the illustrated example also includes a communication device such as a transmitter, a receiver, a transceiver, a modem, a residential gateway, a wireless access point, or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store firmware, software, or data. Examples of such mass storage discs or devices 1028 include magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices or SSDs.

The machine-readable instructions 1032, which may be implemented by the machine-readable instructions of FIGS. 8 and 9, may be stored in the mass storage device 1028, in the volatile memory 1014, in the non-volatile memory 1016, or on at least one non-transitory computer readable storage medium such as a CD or DVD which may be removable.

While an example manner of implementing the DPD estimator circuitry 316 of FIG. 1 is illustrated in FIG. 3, one or more of the elements, processes, or devices illustrated in FIG. 3 may be combined, divided, re-arranged, omitted, eliminated, or implemented in any other way. Further, the capture circuitry 402, the CG solver circuitry 408, the row populator circuitry 410, the row reducer circuitry 414, the regularization circuitry 418, the shaping function circuitry 422, and the shaping control circuitry 426, or, more generally, the example DPD estimator circuitry 316 of FIG. 3, may be implemented by hardware alone or by hardware in combination with software or firmware. Thus, for example, any of the capture circuitry 402, the CG solver circuitry 408, the row populator circuitry 410, the row reducer circuitry 414, the regularization circuitry 418, the shaping function circuitry 422, and the shaping control circuitry 426, or, more generally, the example DPD estimator circuitry 316, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example DPD estimator circuitry 316 of FIG. 3 may include one or more elements, processes, or devices in addition to, or instead of, those illustrated in FIG. 3, or may include more than one of any or all of the illustrated elements, processes and devices.

Flowcharts representative of example machine-readable instructions, which may be executed by programmable circuitry to implement or instantiate the DPD estimator circuitry 316 of FIG. 3 or representative of example operations which may be performed by programmable circuitry to implement or instantiate the DPD estimator circuitry 316 of FIG. 3, are shown in FIGS. 8 and 9. The machine-readable instructions may be one or more executable programs or portion(s) of one or more executable programs for execution by programmable circuitry such as the programmable circuitry 1012 shown in the example programmable circuitry platform 1000 described above in connection with FIG. 10 or may be one or more function(s) or portion(s) of functions to be performed by a different kind of programmable circuitry. In some examples, the machine-readable instructions cause an operation, a task, etc., to be carried out or performed in an automated manner in the real world. As used herein, “automated” means without human involvement.

The program may be embodied in instructions (e.g., software or firmware) stored on one or more non-transitory computer readable or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 8 and 9, many other methods of implementing the example DPD estimator circuitry 316 may alternatively be used. For example, the order of execution of the blocks of the flowchart(s) may be changed, or some of the blocks described may be changed, eliminated, or combined. Any or all of the blocks of the flow chart may be implemented by one or more hardware circuits (e.g., processor circuitry, discrete or integrated analog or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., for them to be directly readable, interpretable, or executable by a computing device or other machine. For example, the machine-readable instructions may be stored in multiple parts, which are individually compressed, encrypted, or stored on separate computing devices, such that the parts when decrypted, decompressed, or combined form a set of computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include instructions or program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, Csharp, Perl, Python, JavaScript, HyperText Markup Language (HTML), Structured Query Language (SQL), Swift, etc.

As mentioned above, the example operations of FIGS. 8 and 9 may be implemented using executable instructions (e.g., computer readable or machine-readable instructions) stored on one or more non-transitory computer readable or machine-readable media. As used herein, the terms non-transitory computer readable medium, non-transitory computer readable storage medium, non-transitory machine-readable medium, or non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, or for caching of the information). As used herein, the terms “non-transitory computer readable storage device” and “non-transitory machine-readable storage device” are defined to include any physical (mechanical, magnetic or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, or redundant array of independent disks (RAID) systems. As used herein, the term “device” refers to physical structure such as mechanical or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” refers to implementations including any of (1) at least one A, (2) at least one B, or (3) at least one A and at least one B. Similarly, as used herein in the context of describing structures, components, items, objects and/or things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is not feasible or advantageous.

As used herein, connection references (e.g., attached, coupled, connected, and joined) may include intermediate members between the elements referenced by the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses direct communication or indirect communication through one or more intermediary components, and does not require direct physical (e.g., wired) communication or constant communication, but rather also includes selective communication at periodic intervals, scheduled intervals, aperiodic intervals, or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions that enable configuration or structuring of the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., or any combination(s) thereof), and orchestration technology (e.g., application programming interface(s) (API(s)) that may assign computing task(s) to whichever one(s) of the multiple types of programmable circuitry is/are suited and available to perform the computing task(s).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

From the foregoing, it will be appreciated that example systems, apparatus, articles of manufacture, and methods have been described that apply a shaping function to DPD coefficients such that pre-distortion of an input signal can vary across both time and frequency. Described systems, apparatus, articles of manufacture, and methods improve the efficiency of using a computing device by assigning weight values to frequency bands responsive to signal profile data, ACLR profile data, and a feedback signal. Shaping function circuitry described herein also converts the frequency-domain weights into time-domain shaping parameters. The shaping function circuitry applies the shaping parameters by modifying individual DPD coefficients such that more pre-distortion occurs in some frequency bands than in others. As a result, devices implemented with the teachings described herein exhibit greater overall performance than other devices when a signal is transmitted with high bandwidth or high power. To reduce computational usage and increase efficiency, shaping control circuitry described herein prevents the use of the shaping function when DPD convergence has not yet reached a steady state, the signal profile data changes, or the ACLR profile data changes. Described systems, apparatus, articles of manufacture, and methods are accordingly directed to one or more improvement(s) in the operation of a machine such as a computer or other electronic and/or mechanical device.

What is claimed is:

1. An apparatus comprising:
monitor circuitry having a terminal, the monitor circuitry configured to:
determine a range of out-of-band frequencies responsive to adjacent channel leakage ratio data; and
generate weight values responsive to electromagnetic emissions within the range of out-of-band frequencies of a first signal;
function applier circuitry having a first terminal coupled to the terminal of the monitor circuitry and a second terminal, the function applier circuitry configured to use the weight values to modify a pre-distortion function; and
digital pre-distortion (DPD) corrector circuitry having a terminal coupled to the second terminal of the function applier circuitry, the DPD corrector circuitry configured to apply the modified pre-distortion function to generate a second signal, wherein the second signal exhibits fewer emissions in the range of out-of-band frequencies than the first signal during transmission.

2. The apparatus of claim 1, wherein the apparatus further includes capture circuitry having a terminal coupled to a second terminal of the monitor circuitry, the capture circuitry configured to generate the first signal responsive to a transmission from power amplifier circuitry.

3. The apparatus of claim 1, wherein:
the monitor circuitry is further configured to generate the weight values responsive to signal profile data; and
the signal profile data describes an in-band frequency range of an input signal.

4. The apparatus of claim 3, wherein:
the weight values are first weight values; and
responsive to a change in the signal profile data or the adjacent channel leakage ratio data, the monitor circuitry is configured to stop generating the first weight values and begin generating second weight values, the second weight values corresponding to a different modification of the pre-distortion function than the first weight values.

5. The apparatus of claim 1, wherein the monitor circuitry is configured to generate the weight values and the function applier circuitry is configured to modify the pre-distortion function in response to a determination that performance of the DPD circuitry has converged to a steady state.

6. The apparatus of claim 1, wherein:
the apparatus further includes parameter generator circuitry having a first terminal coupled to the monitor circuitry and a second terminal coupled to the function applier circuitry, the parameter generator circuitry configured to convert the weight values into shaping parameters; and
wherein the function applier circuitry is configured to use the shaping parameters to modify a nonlinear term corresponding to the pre-distortion function.

7. The apparatus of claim 6, wherein:
the function applier circuitry is configured to use the shaping parameters to modify elements of a nonlinear matrix and an error vector; and
the apparatus further includes conjugate gradient solver circuitry configured to produce coefficients responsive to the modified elements of the nonlinear matrix and the error vector, the modified pre-distortion function to include the coefficients.

8. An apparatus including:
processor circuitry having a terminal, the processor circuitry configured to generate adjacent channel leakage ratio data that describes a range of out-of-band frequencies;
monitor circuitry having a first terminal coupled to the terminal of the monitor circuitry and a second terminal, the monitor circuitry configured to generate weight values responsive to electromagnetic emissions within the range of out-of-band frequencies of a first signal;
parameter generator circuitry having a first terminal coupled to the second terminal of the monitor circuitry and a second terminal, the parameter generator circuitry configured to convert the weight values into shaping parameters;
function applier circuitry having a first terminal coupled to the second terminal of the parameter generator circuitry and a second terminal, the function applier circuitry configured to use the shaping parameters to modify a pre-distortion function; and
digital pre-distortion (DPD) corrector circuitry having a terminal coupled to the second terminal of the function applier circuitry, the DPD corrector circuitry configured to apply the modified pre-distortion function to generate a second signal; and
power amplifier circuitry to amplify an amount of power used to transmit the second signal, wherein the second signal exhibits fewer emissions in the range of out-of-band frequencies than the first signal during transmission.

9. The apparatus of claim 8, wherein:
the digital pre-distortion (DPD) corrector is circuitry to apply the modified pre-distortion function to counteract nonlinearity that is introduced into the second signal by the power amplifier circuitry; and
the nonlinearity generated by the power amplifier circuitry causes the emissions in the out-of-band frequencies.

10. The apparatus of claim 8, wherein the apparatus further includes:
feedback circuitry having a first terminal coupled to the power amplifier circuitry and a second terminal, the feedback circuitry configured to generate a feedback signal that characterizes a transmission from the power amplifier circuitry; and
capture circuitry having a terminal coupled to the second terminal of the feedback circuitry, the capture circuitry configured to generate the first signal by sampling the feedback signal.

11. The apparatus of claim 8, wherein:
the monitor circuitry is further configured to generate the weight values responsive to signal profile data; and
the signal profile data describes an in-band frequency range of an input signal.

12. The apparatus of claim 11, wherein the monitor circuitry is configured to obtain the signal profile data through a third terminal that is coupled to the processor circuitry.

13. The apparatus of claim 11, wherein the monitor circuitry is configured to obtain the signal profile data through a third terminal coupled to Crest Factor Reduction (CFR) circuitry.

14. The apparatus of claim 11, wherein:
the weight values are first weight values; and
responsive to a change in the signal profile data:
the monitor circuitry is configured to stop generating the first weight values and begin generating second weight values; and
the function applier circuitry is configured to use the second weight values to apply a different modification to the pre-distortion function than was applied using the first weight values.

15. The apparatus of claim 11, wherein the function applier circuitry is configured to use the shaping parameters to modify an individual term corresponding to the pre-distortion function.

16. The apparatus of claim 8, wherein the monitor circuitry is configured to generate the weight values and the function applier circuitry is configured to modify the pre-distortion function in response to a determination that performance of the DPD circuitry has converged to a steady state.

17. The apparatus of claim 11, wherein:
the weight values are first weight values; and
responsive to a change in the adjacent channel leakage ratio data, the monitor circuitry is configured to stop generating the first weight values and begin generating second weight values, the second weight values corresponding to a different modification of the pre-distortion function than the first weight values.

18. An apparatus comprising:
memory having a terminal, the memory configured to store machine-readable instructions and adjacent channel leakage ratio data; and
programmable circuitry having a terminal coupled to the terminal of the memory, the programmable circuitry configured to execute the machine-readable instructions to:
determine a range of out-of-band frequencies responsive to adjacent channel leakage ratio data;
generate weight values responsive to instances where energy corresponding to a first signal is transmitted within the range of out-of-band frequencies;
convert the weight values into shaping parameters;
modify a pre-distortion function responsive to the shaping parameters; and
apply the modified pre-distortion function to generate a second signal, the second signal to exhibit fewer electromagnetic emissions in the range of out-of-band frequencies than the first signal during transmission.

19. The apparatus of claim 18, wherein:
the weight values are first weight values; and
the programmable circuitry is configured to, responsive to a change in signal profile data or the adjacent channel leakage ratio data, stop generating the first weight values and begin generating second weight values, the second weight values corresponding to a different modification of the pre-distortion function than the first weight values.

20. The apparatus of claim 18, wherein the programmable circuitry is configured to generate the weight values and modify the pre-distortion function in response to a determination that DPD performance has converged to a steady state.
